(19) United States
(12) Patent Application Publication
(10) Pub. No.: US 2025/0273480 A1
(43) Pub. Date: Aug. 28, 2025

(54) SEMICONDUCTOR DEVICE WITH IMPROVED HEAT DISSIPATION AND A METHOD FOR FORMING THE SAME

(71) Applicant: JCET STATS ChipPAC Korea Limited, Incheon (KR)

(72) Inventors: SeungHyun LEE, Incheon (KR); YeoJun YUN, Incheon (KR); HeeSoo LEE, Incheon (KR)

(21) Appl. No.: 19/056,780

(22) Filed: Feb. 19, 2025

(30) Foreign Application Priority Data
Feb. 22, 2024 (CN) 202410197128.5

(51) Int. Cl. H01L 21/48; H01L 21/027; H01L 21/768; H01L 23/00; H01L 23/367; H01L 25/16; H10B 80/00; H10D 80/30

(52) U.S. Cl. CPC H01L 21/4875; H01L 21/0274; H01L 21/4878; H01L 21/76877; H01L 23/3675; H01L 23/3677; H01L 24/08; H01L 24/16; H01L 24/80; H01L 25/16; H01L 2224/08145; H01L 2224/16225; H01L 2224/80895; H01L 2224/80896; H01L 2225/06517; H01L 2225/06589; H01L 2924/1431; H10B 80/00; H10D 80/30

(57) ABSTRACT

A method for forming a semiconductor device is provided. The method includes providing a base material block; forming a photoresist layer; forming ultraviolet-proof particles; patterning the photoresist layer through the ultraviolet-proof particles; etching the base material block through the patterned photoresist layer to form an array of vertical holes; filling in the array of vertical holes a thermally conductive material to form an array of thermally conductive vias, wherein the array of thermally conductive vias and the base material block constitute a thermally conductive block; providing a semiconductor die stack with a primary semiconductor die and an auxiliary semiconductor die, wherein the primary semiconductor die comprises a top surface having a first region and a second region besides the first region, wherein the auxiliary semiconductor die is attached onto the first region; attaching the thermally conductive block on the second region; and attaching a heat spreader.

### TECHNICAL FIELD

The present application generally relates to semiconductor technology, and more particularly, to a semiconductor device with improved heat dissipation and a method for forming a semiconductor device.

### BACKGROUND OF THE INVENTION

The semiconductor industry is constantly faced with complex integration challenges as consumers want their electronics to be smaller, faster and higher performance with more and more functionalities packed into a single device. In order to meet the needs of the consumers, more and more electronic components are tightly integrated. Yet, due to the tight integration, heat generated from an electronic component may be blocked by other electronic components, heat dissipation may not be ideal, and the performance of the semiconductor device may be harmed. Therefore, a need exists for a semiconductor device with improved heat dissipation.

### SUMMARY OF THE INVENTION

An objective of the present application is to provide a semiconductor device with improved heat dissipation.

According to an aspect of embodiments of the present application, a method for forming a semiconductor device is provided. The method may comprise: providing a base material block; forming a photoresist layer on the base material block; forming ultraviolet-proof particles on the photoresist layer; patterning the photoresist layer through the ultraviolet-proof particles; etching the base material block through the patterned photoresist layer to form an array of vertical holes that extend at least partially into the base material block; filling in the array of vertical holes a thermally conductive material to form an array of thermally conductive vias in the base material block, wherein the array of thermally conductive vias and the base material block constitute a thermally conductive block; providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die; attaching the thermally conductive block on the second region of the top surface of the primary semiconductor die; and attaching a heat spreader on the thermally conductive block and the auxiliary semiconductor die to form the semiconductive device.

According to an aspect of embodiments of the present application, a method for forming a thermally conductive block is provided. The method may comprise: providing a base material block; forming a photoresist layer on the base material block; forming ultraviolet-proof particles on the photoresist layer; patterning the photoresist layer through the ultraviolet-proof particles; etching the base material block through the patterned photoresist layer to form an array of vertical holes that extend at least partially into the base material block; and filling in the array of vertical holes a thermally conductive material to form an array of thermally conductive vias in the base material block, wherein the array of thermally conductive vias and the base material block constitute the thermally conductive block.

According to another aspect of embodiments of the present application, a semiconductor device is provided. The semiconductor device may comprise: a primary semiconductor die with a top surface, wherein the top surface comprising a first region and a second region besides the first region; an auxiliary semiconductor die attached onto the first region of the top surface of the primary semiconductor die; a thermally conductive block attached on the second region of the top surface of the primary semiconductor die, wherein the thermally conductive block comprises a base material block and an array of thermally conductive vias extending therethrough; a heat spreader attached on the thermally conductive block and the auxiliary semiconductor die.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 shows a cross-sectional view illustrating a semiconductor device 100 according to an embodiment of the present application.

FIG. 2 shows an exemplary thermally conductive block 200 according to an embodiment of the present application.

FIGS. 3A to 3F show steps for forming a thermally conductive block according to an embodiment of the present application.

FIGS. 4A to 4C show cross-sectional views illustrating a method for forming a semiconductor device according to an embodiment of the present application.

FIG. 5 is a scanning electron microscopy image of a front surface of a patterned base material block before metal or other thermally conductive material is filled in cavities of the base material block.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

A semiconductor device may include multiple electronic components especially multiple semiconductor dice which may generate significant heat during operation. In order to assist thermal dissipation for the semiconductor dice, a semiconductor device may include auxiliary components to assist thermal dissipation. Yet, conventional semiconductor devices may not have satisfactory heat dissipation performance in view of the high integration level of latest semiconductor dice such as central processing units or digital processing units. Thus, the inventors of the present invention provide herein a new thermally conductive block to improve heat dissipation for semiconductor devices. In particular, the thermally conductive block may include high-density metal vias which has a nano-sized to micro-sized diameter. The high- density metal vias may improve significantly the thermal conductivity of the blocks while substantially maintaining its thermal expansion characteristics.

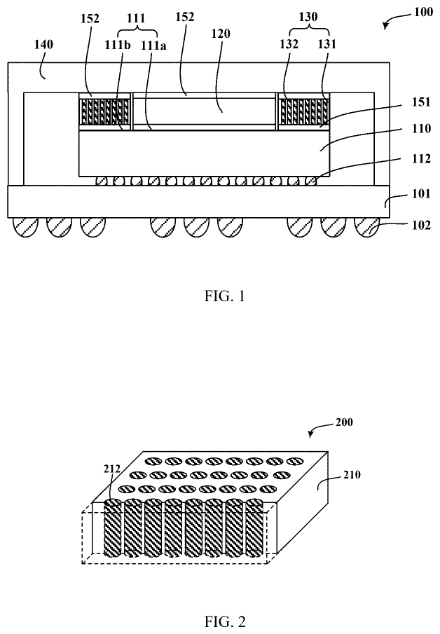

FIG. 1 shows a cross-sectional view illustrating a semiconductor device 100 according to an embodiment of the present application.

As shown in FIG. 1, the semiconductor device 100 includes a primary semiconductor die 110 and an auxiliary semiconductor die 120 attached thereon, optionally through a bottom thermal interface material (TIM) layer 151. Specifically, the auxiliary semiconductor die 120 is attached to a first region 111a of a top surface 111 of the primary semiconductor die 110, and the auxiliary semiconductor die 120 does not cover a second region 111b of the top surface 111 of the primary semiconductor die 110. In some embodiments, the primary semiconductor die 110 and/or the auxiliary semiconductor die 120 may include a logic chip, a microcontroller, a microprocessor, a network processor, a power management processor, an audio processor, a video processor, a digital signal processor (DSP), an application specific integrated circuit (ASIC), a radio frequency circuit, a wireless baseband system on chip (SoC) processor, a sensor, a memory controller, a memory device, etc. In a specific example, the primary semiconductor die 110 may be a logic chip and the auxiliary semiconductor die 120 may be a memory chip. In some embodiments, the primary semiconductor die 110 and the auxiliary semiconductor die 120 are bonded together by hybrid bonding. In some embodiments, the hybrid bonding of the primary semiconductor die 110 and the auxiliary semiconductor die 120 can include a bonding surface (not shown) with a dielectric material and conductive interconnect structures that extend through the dielectric material. Preferably, the conductive interconnect structures may include copper posts. In some embodiments, the primary semiconductor die 110 may include through silicon vias (TSVs) (not shown) for desired vertical electrical connection.

In the above-mentioned stacked semiconductor dice, heat generated by the primary semiconductor die 110 may be blocked by the auxiliary semiconductor die 120. The blocked heat conduction may undesirably harm the performance of the overall device. In view of this, auxiliary components assisting thermal dissipation are included in the semiconductor device 100 as illustrated below.

Still referring to FIG. 1, two thermally conductive blocks 130 are attached on the second region 111b of the top surface 111 of the primary semiconductor die 110, optionally through the bottom TIM layer 151. Each thermally conductive block 130 has a profile that generally conforms to that of the combined semiconductor dice 110 and 120. In some embodiments, the two thermally conductive block 130 at least partially cover the second region 111b of the top surface 111 of the primary semiconductor die 110. Preferably, the two thermally conductive blocks 130 may fully cover the second region 111b of the primary semiconductor die 110. Specifically, each thermally conductive block 130 may include a base material block 131 and an array of thermally conductive vias 132 extending through the base material block 131. The array of thermally conductive vias 132 extends vertically between a top surface and a bottom surface of the thermally conductive block 130 so as to form respective thermal paths through the thermally conductive block 130. Therefore, the thermally conductive block 130 may transfer out heat generated by the primary semiconductor die 110 via the thermally conductive vias 132.

A heat spreader 140 is attached on the thermally conductive blocks 130 and the auxiliary semiconductor die 120. The heat spreader 140 may take any desirable form. In some embodiments, the heat spreader 140 includes a lid and multiple lateral portions extending from the lid. Preferably, the lid and the lateral portions are integrally formed as a single piece. As shown in FIG. 1, when the primary semiconductor die 110 is attached on a substrate 101 through solder bumps 112 or other interconnect structures, the heat spreader 140 may be attached partially on the substrate 101, and partially on the auxiliary semiconductor die 120 and the thermally conductive blocks 130. In this way, the heat spreader 140 may receive heat from the semiconductor die 120 and the thermally conductive blocks 130 and dissipate the heat to the external environment. In some embodiments, the lid can be disposed on the auxiliary semiconductor die 120 and the thermally conductive blocks 130 through a top thermal interface material (TIM) layer 152. Either or both of the TIM layers 151 and 152 may include thermal greases, thermal adhesives, thermal gap fillers, liquid metal, and solder paste, for example. Under the substrate 101, solder bumps 102 may be formed for mounting the semiconductor device 100 onto an external device such as a printed circuit board.

In the embodiment shown in FIG. 1, two thermally conductive blocks 130 are attached on the substrate 101 for heat transfer. However, the number of the thermally conductive blocks 130 and their positions or shapes may be adjusted depending on the heat dissipation requirement for the semiconductor device 100. For example, one thermally conductive block may be attached on a logic circuit region of a primary semiconductor die where a significant portion of heat is generated and desires heat dissipation, with the other region of the primary semiconductor die not attached with the thermally conductive block.

FIG. 2 shows an exemplary thermally conductive block 200 according to an embodiment of the present application. The thermally conductive block 200 may be used as the thermally conductive block 130 shown in FIG. 1, for example.

As shown in FIG. 2, the thermally conductive block 200 includes a base material block 210 such as a silicon block, and an array of thermally conductive vias 212 which extend through the base material blocks 210. It can be appreciated that although it is shown in FIG. 2 each of the thermally conductive vias 212 has a cylindrical shape, in some other embodiments, the thermally conductive vias 212 may have any other desired shapes, such as a hexagonal prism shape, as long as they can vertically extend through the base material block 210.

Each of the thermally conductive vias 212 may have substantially the same diameter when measured at a top surface or a bottom surface of the base material block 210. In some embodiments, the diameter of the thermally conductive vias 212 may range from 300 nm to 1300 nm, or preferably 700 nm to 1100 nm. It can be appreciated that the diameter of the thermally conductive vias 212 may be a statistical value, e.g., an average value or a median value, for all the thermally conductive vias 212, and it is not required all the thermally conductive vias 212 must have a diameter within the specific range, for example, the range from 300 nm to 1300 nm. Furthermore, each two adjacent vias in the array of thermally conductive vias 212 may have a distance or pitch ranging from 50 nm to 50 micrometers, or preferably from 100 nm to 5 micrometers, or more preferably from 150 nm to 500 nm. Similarly, the distance or pitch may be a statistical value such as an average value or a median value. It can be appreciated that the denser the thermally conductive vias 212 are, the higher thermal conductivity they can exhibit. Furthermore, the thermally conductive vias 212 may also improve the strength of the thermally conductive block 200, if metal such as copper is used for forming the vias 212.

However, a ratio in volume of the thermally conductive vias 212 to the base material block 210 should be less than 70%, or preferably less than 50% ˜30%, to avoid that the thermally conductive vias 212 significantly affect thermal expansion characteristics of the overall thermally conductive block 200. As aforementioned, a significant change in the thermal expansion characteristics of the thermally conductive block 200 may produce undesired mismatch in thermal expansion between the thermally conductive block 200 and the auxiliary semiconductor die (e.g., the auxiliary semiconductor die 120 shown in FIG. 1) which may be juxtaposed with each other on a substrate, thereby producing a thermal stress that may harm a semiconductor device incorporating these components.

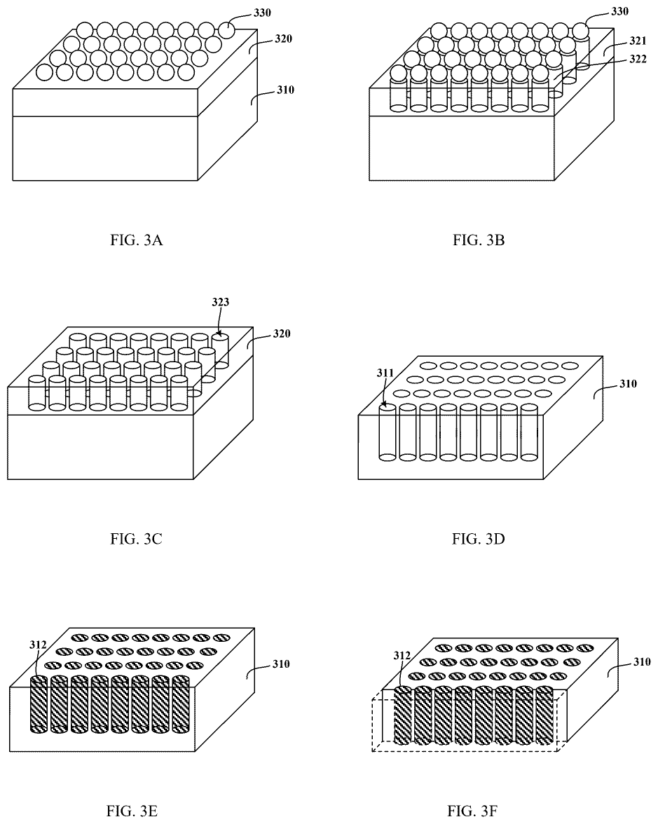

FIG. 3A to 3F show a method for forming a thermally conductive block according to an embodiment of the present application. For example, the method may be used to form the thermally conductive block 200 shown in FIG. 2.

As shown in FIG. 3A, a base material block 310 is provided. In some embodiments, the base material block 310 may be a portion or a unit of a base material wafer such as a silicon wafer, along with other base material blocks in the same base material wafer. The base material blocks may be processed together with the following steps and singulated into individual pieces after all the steps are completed. A photoresist layer 320 is formed on the base material block 310, for example, by spin-coating. In the embodiment, the photoresist layer 320 may be a negative photoresist which exhibits an anti-etch characteristics after ultraviolet exposure. However, it can be appreciated that a positive photoresist can be similarly used.

Next, ultraviolet-proof particles 330 such as polystyrene particles or SiO₂ particles are formed on the photoresist layer 320. The ultraviolet-proof particles 330 may be used as a mask for the photoresist layer 320 during a subsequent ultraviolet exposure step. In some embodiments, the ultraviolet-proof particles 330 may be nanospheres, which may have a diameter ranging from 300 nm to 1300 nm, for example.

In some embodiments, the ultraviolet-proof particles 330 may be formed on the photoresist layer 320 using a floating technique. In particular, the base material block 310 or the wafer containing the base material block 310 may be immersed in a piranha solution for more than 2 hours to obtain a hydrophilic surface for the base material block 310, or particularly for the photoresist layer 320 on the base material block 310. Then the base material block 310 may be rinsed in ethanol and de-ionized (DI) water to wash away the piranha solution. After the rinse, an ultraviolet-proof particle solution mixed with isopropyl alcohol (IPA) may be dropped onto the base material block 310. The ultraviolet-proof particle solution may have a particle diameter of 1000 nm, which may be commercially available from various vendors such as Thermo Fisher Scientific. Next, the particle solution may be distributed on the hydrophilic surface of the base material block 310, which may then be slowly immersed in water in a beaker at about a 30° tilt angle. The ultraviolet-proof particles may float on the surface of the DI water as a result of this process. When a sufficient amount of the ultraviolet-proof particles has been floated on the water surface by repeating the above series of processes, ultraviolet particle islands may form on the water surface show iridescent reflections. A drop of diluted triton-100X, which can modify the water surface tension, may be added to self-assemble the ultraviolet-proof particles into a large-area monolayer. Afterwards, the aggregated ultraviolet-proof particles may be raised over the base material block 310, and water is allowed to evaporate naturally at room temperature. In this way, close-packed ultraviolet-proof particles can be formed on the photoresist layer 320. It can be appreciated that any suitable methods other than the floating technique may be used to form the ultraviolet-proof particles on the photoresist layer 320.

Next, as shown in FIGS. 3B and 3C, the photoresist layer can be patterned through the ultraviolet-proof particles 330. In particular, the photoresist layer may be exposed through the mask consisted of the ultraviolet-proof particles 330 to ultraviolet radiation. The ultraviolet exposure transforms the photoresist layer into two portions, i.e., an exposed portion 321 which is not blocked by the ultraviolet-proof particles 330 and a non-exposed portion 322 which is blocked by the ultraviolet-proof particles 330. Due to the characteristics of the positive photoresist, the composition of the exposed portion 321 may cross link and exhibit the anti-etch characteristics to a developing solution, while the non-exposed portion 322 may not. Afterwards, the ultraviolet-proof particles 330 can be removed from the photoresist layer, and the base material block 310 with the exposed photoresist layer may be developed in a developing solution. Accordingly, as shown in FIG. 3C, the non-exposed portion of the photoresist layer 320 may be dissolved in the developing solution, thereby forming respective cavities 323 in the photoresist layer 320.

It can be appreciated that since the ultraviolet-proof particles are used as a mask for patterning the photoresist layer 320 during the ultraviolet exposure. The shape and size of the ultraviolet-proof particles may be similar to the section of the cavity 323 formed in the photoresist layer 320. For example, when the size of the ultraviolet-proof particles reduces, the diameter of the cavities 323 in the photoresist layer 320 may also reduce. In some embodiments, the ultraviolet-proof particles may have a size that is slightly greater than that of the cavities 323 in the photoresist layer 320. For example, when the ultraviolet-proof particles have a size or diameter of about 500 nm, the cavities 323 can be formed with a diameter or size ranging from 200 nm to 400 nm. Furthermore, when the ultraviolet-proof particles have a size or diameter of about 1000 nm, the cavities 323 can be formed with a diameter or size ranging from 500 nm to 800 nm, for example.

Next, as shown in FIG. 3D, the base material block 310 may be etched through the patterned photoresist layer to form an array of vertical holes 311 that extend at least partially into the base material block 310. In some embodiments, the vertical holes 311 may be formed using a deep reaction ion etching (RIE) process. In some other embodiments, the vertical holes 311 may be formed using a metal-assisted chemical (MAC) etching process. Metal such as Au, Ag, Cu, Al and solutions such as that composed of HF, H₂O₂, KMnO₄ can be used for the metal-assisted chemical etching process. Both the deep RIE process and the MAC etching process can have straight etching reactions, and thus, the vertical holes 311 so formed can be controlled with a generally straight direction with respect to the base material block 310. Afterwards, the patterned photoresist layer can be removed from the base material block 310. It can be appreciated that the cavities 311 may have a depth equal to or smaller than a thickness of the base material block 310, i.e., the base material block 310 may be either etch through or not through. In some embodiments, the depth of the vertical holes 311 may range from 10 micrometers to 300 micrometers, or preferably range from 30 micrometers to 200 micrometers. It can be appreciated that the depth of the vertical holes 311, i.e., the thermally conductive vias to be formed in the base material block 310, may vary depending on the thickness of an auxiliary semiconductor die.

FIG. 5 is a scanning electron microscopy image of a front surface of a patterned base material block before metal or other thermally conductive material is filled in cavities of the base material block. As shown in FIG. 5, the cavities are formed in a regular pattern with a diameter of about 350 nm and a pitch of about 150 nm.

Next, as shown in FIG. 3E, a thermally conductive material such as copper or any other suitable metals may be filled in the array of vertical holes to form an array of thermally conductive vias 312 in the base material block 310. For example, the thermally conductive material may be deposited using a physical vaporization deposition process, or a process combining sputtering and plating.

In the embodiment, the base material block 310 may not be etched through during the etching process as shown in FIG. 3D. Accordingly, as shown in FIG. 3F, a back grinding process may be performed to a bottom side of the base material block 310 to remove an excess thickness of the base material block 310. The grinding process may therefore expose bottom ends of the thermally conductive vias 312 from the base material block 310. In some embodiments, the back grinding process may further remove a portion of the thickness of the base material block 310 containing the thermally conductive vias 312 to form the thermally conductive vias 312 with the same height. As such, the thermally conductive vias 312 can be exposed from both the top surface and the bottom surface of the base material block 310. In this way, a thermally conductive block with nanosized or micro-sized thermally conductive vias can be obtained.

It can be seen that the above method for forming the thermally conductive block uses the array of ultraviolet-proof particles instead of a specific photo mask for lithography, which is low is manufacture cost, for example, compared with through holes vias (TSVs) which may be formed using e-beam etching. Furthermore, in some other embodiments, imprinting, e-beam lithography or other suitable processes may be used to pattern the photoresist layer.

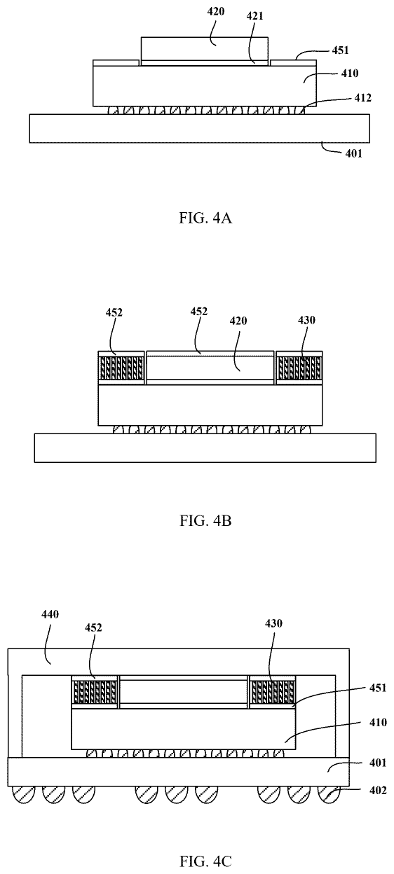

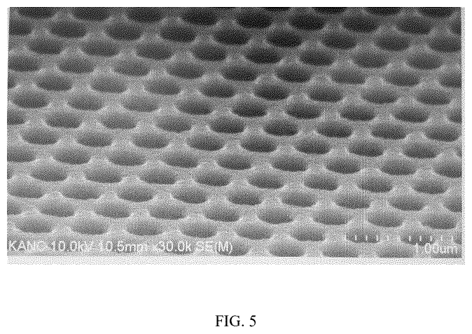

Referring to FIGS. 4A to 4C, various steps of a method for forming a semiconductor device are illustrated according to another embodiment of the present application. For example, the method may be used to form the semiconductor device 100 shown in FIG. 1.

Referring to FIG. 4A, a substrate 401 is provided. The substrate 401 can support and provide electrical connections for semiconductor dice or electronic components mounted thereon. A semiconductor package or assembly may be mounted on a top surface of the substrate 401 through solder bumps 412 or other similar interconnect structures. The package includes a primary semiconductor die 410 and an auxiliary semiconductor die 420 bonded together through a bonding layer 421, which are further stacked on a top surface of the primary semiconductor die 410. Afterwards, a thermally conductive layer 451 is formed on a top surface of the primary semiconductor die 410, in a region not covered by the auxiliary semiconductor die 420, serving as a TIM layer.

Next, as shown in FIG. 4B, one or more thermally conductive blocks 430 may be formed on the thermally conductive layer 430. The thermally conductive blocks 430 may have a height that is substantially equal to that of the auxiliary semiconductor die 420. In some embodiments, two or more layers of thermally conductive blocks 430 may be stacked together in parallel with the auxiliary semiconductor die 420, when a single thermally conductive block 430 may not have a thickness that is equal to that of the auxiliary semiconductor die 420. An additional thermally conductive layer 430 may be further formed on both of the thermally conductive blocks 430 and the auxiliary semiconductor die 420, serving as another TIM layer. The thermally conductive blocks 430 may have a structure similar to or the same as that of the thermally conductive block 200 shown in FIG. 2.

Next, referring to FIG. 4C, a heat spreader 440 may be attached on the substrate. The heat spreader 440 may be thermally coupled to the auxiliary semiconductor die 420 and the thermally conductive blocks 430 through the top thermally conductive layer 452. As such, thermal paths can be formed from the primary semiconductor die 410 to the heat spreader 440 through the thermally conductive blocks 430, which exhibit better thermal conductivity compared with conventional silicon or similar blocks, solder bumps 402 may be further formed on a bottom surface of the substrate 401 to complete the semiconductor device.

It should be noted that although the thermally conductive blocks according to the embodiments of the present application are exemplarily used in the semiconductor device shown in FIG. 1, any other types of semiconductor devices or other electronic device may incorporate such thermally conductive blocks for heat transfer and dissipation.

The discussion herein included numerous illustrative figures that showed various portions of a semiconductor device and method for forming the semiconductor device. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A method for forming a semiconductor device, the method comprising:
providing a base material block;
forming a photoresist layer on the base material block;
forming ultraviolet-proof particles on the photoresist layer;
patterning the photoresist layer through the ultraviolet-proof particles;
etching the base material block through the patterned photoresist layer to form an array of vertical holes that extend at least partially into the base material block;
filling in the array of vertical holes a thermally conductive material to form an array of thermally conductive vias in the base material block, wherein the array of thermally conductive vias and the base material block constitute a thermally conductive block;
providing a semiconductor die stack with a primary semiconductor die and an auxiliary semiconductor die, wherein the primary semiconductor die comprises a top surface having a first region and a second region besides the first region, wherein the auxiliary semiconductor die is attached onto the first region of the top surface of the primary semiconductor die;
attaching the thermally conductive block on the second region of the top surface of the primary semiconductor die; and
attaching a heat spreader on the thermally conductive block and the auxiliary semiconductor die to form the semiconductive device.

2. The method of claim 1, wherein before attaching a heat spreader on the thermally conductive block and the auxiliary semiconductor die, the method further comprises:
forming a first thermal interface layer on the semiconductor die stack, wherein the first thermal interface layer at least partially covers the second region of the top surface of the primary semiconductor die; and
forming a second thermal interface layer on the semiconductor die stack, wherein the second thermal interface layer at least partially covers a top surface of the auxiliary semiconductor die and a top surface of the thermally conductive block.

3. The method of claim 1, wherein patterning the photoresist layer through the ultraviolet- proof particles comprises:
exposing the photoresist layer through the ultraviolet-proof particles to ultraviolet radiation;
removing the ultraviolet-proof particles; and
developing the exposed photoresist layer.

4. The method of claim 1, wherein etching the base material block comprises etching the base material block using deep reactive ion etching or metal-assisted chemical etching.

5. The method of claim 1, wherein after filling in the array of vertical holes a thermally conductive material, the method further comprises:
grinding the base material block to expose the array of thermally conductive vias from the base material block from both a top surface and a bottom surface of the base material block.

6. The method of claim 1, wherein the ultraviolet-proof particles are nanospheres.

7. The method of claim 6, wherein a diameter of the nanospheres ranges from 300 nm to 1300 nm.

8. A method for forming a thermally conductive block, the method comprising:
providing a base material block;
forming a photoresist layer on the base material block;
forming ultraviolet-proof particles on the photoresist layer;
patterning the photoresist layer through the ultraviolet-proof particles;
etching the base material block through the patterned photoresist layer to form an array of vertical holes that extend at least partially into the base material block; and
filling in the array of vertical holes a thermally conductive material to form an array of thermally conductive vias in the base material block, wherein the array of thermally conductive vias and the base material block constitute the thermally conductive block.

9. The method of claim 8, wherein patterning the photoresist layer through the ultraviolet-proof particles comprises:
exposing the photoresist layer through the ultraviolet-proof particles to ultraviolet radiation;
removing the ultraviolet-proof particles; and
developing the exposed photoresist layer.

10. The method of claim 8, wherein etching the base material block comprises etching the base material block using deep reactive ion etching or metal-assisted chemical etching.

11. The method of claim 8, wherein after filling in the array of vertical holes a thermally conductive material, the method further comprises:
grinding the base material block to expose the array of thermally conductive vias from the base material block from both a top surface and a bottom surface of the base material block.

12. The method of claim 8, wherein the ultraviolet-proof particles are nanospheres.

13. The method of claim 12, wherein a diameter of the nanospheres ranges from 300 nm to 1300 nm.

14. A semiconductor device, comprising:
a primary semiconductor die with a top surface, wherein the top surface comprises a first region and a second region besides the first region;
an auxiliary semiconductor die attached onto the first region of the top surface of the primary semiconductor die;
a thermally conductive block attached on the second region of the top surface of the primary semiconductor die, wherein the thermally conductive block comprises a base material block and an array of thermally conductive vias extending therethrough; and
a heat spreader attached on the thermally conductive block and the auxiliary semiconductor die.

15. The semiconductor device of claim 14, further comprising:
a first thermal interface layer formed on the primary semiconductor die, wherein the first thermal interface layer at least partially covers the second region of the top surface of the primary semiconductor die; and
a second thermal interface layer formed on the auxiliary semiconductor die and the thermally conductive block, wherein the second thermal interface layer at least partially covers a top surface of the auxiliary semiconductor die and a top surface of the thermally conductive block; and
wherein the heat spreader is thermally coupled to the auxiliary semiconductor die through the second thermal interface layer, and the heat spreader is thermally coupled to the primary semiconductor die through the second thermal interface layer, the thermally conductive block and the first thermal interface layer.

16. The semiconductor device of claim 14, wherein the semiconductor device further comprises a substrate, and wherein the primary semiconductor die and the heat spreader are attached on the substrate.

17. The semiconductor device of claim 14, wherein each thermally conductive via of the array of thermally conductive vias is formed as a cylinder, and wherein a diameter of each thermally conductive via of the array of thermally conductive vias ranges from 300 nm to 1300 nm.
